(19) United States
(12) Patent Application Publication
(10) Pub. No.: US 2026/0264268 A1
(43) Pub. Date: Sep. 10, 2026

(54) SUCTION COLLET AND METHOD FOR MANUFACTURING OPTICAL COMPONENT

(71) Applicant: SUMITOMO ELECTRIC INDUSTRIES, LTD., Osaka (JP)

(72) Inventor: Michio SUZUKI, Osaka (JP)

(21) Appl. No.: 19/551,867

(22) Filed: Feb. 27, 2026

(30) Foreign Application Priority Data
Mar. 4, 2025 (JP) 2025-034005

(51) Int. Cl. B25J 15/06; B23K 1/005

(52) U.S. Cl. CPC B25J 15/0616; B23K 1/0056

(57) ABSTRACT

A suction collet according to one embodiment includes a main body portion including a hollow portion for taking in air; and a tip portion for holding a component by suction through the intake of air in the hollow portion. The tip portion includes, on an outer periphery of the tip portion, a reflection portion that is a gold-plated portion.

### CROSS REFERENCE TO RELATED APPLICATIONS

This application claims priority based on Japanese Patent Application No. 2025-034005 filed on Mar. 4, 2025, and the entire contents of the Japanese patent application are incorporated herein by reference.

### TECHNICAL FIELD

The present disclosure relates to a suction collet and a method for manufacturing an optical component.

### BACKGROUND

Japanese Unexamined Publication No. H7-176549 discloses a die bonding apparatus that holds a chip by suction using a suction collet. The suction collet that holds the chip by suction is movable upward and downward by an up-down stage and in a left-right direction by a suction collet X-stage. A minute suction hole is formed in a central portion of the suction collet. A vacuum source draws a vacuum in the suction hole, thereby causing the suction collet to hold a chip by suction.

Japanese Unexamined Utility Model Publication No. H1-72973 discloses a reflow soldering apparatus. In the reflow soldering apparatus, a semiconductor device having a large heat capacity is placed on a circuit pattern of a substrate, and the substrate on which the semiconductor device is placed is placed on a moving bed. The semiconductor device is heated by a first heating portion and simultaneously heated by a laser beam from a laser device.

Japanese Unexamined Publication No. 2017-17263 discloses a module-to-substrate connected structure including a printed circuit board, a power semiconductor module, and a thin substrate. The printed circuit board includes a control signal wiring and a first connecting land, and the thin substrate includes an insulating thin film, a metal foil, and a second connecting land. The first connecting land and the second connecting land are joined to each other by soldering, and laser heating or soldering iron heating is applied to the soldering. In the laser heating, the first connecting land and the second connecting land are irradiated with semiconductor laser light having a wavelength of approximately 900 nm and a spot diameter of 0.5 mm.

### SUMMARY

A suction collet according to the present disclosure includes a main body portion including a hollow portion for taking in air; and a tip portion for holding a component by suction through the intake of air in the hollow portion. The tip portion includes, on an outer periphery of the tip portion, a reflection portion that is a gold-plated portion.

### BRIEF DESCRIPTION OF THE DRAWINGS

FIG. 1 is a perspective view illustrating a suction collet according to an embodiment.

FIG. 2 IS A SIDE VIEW ILLUSTRATING THE SUCTION COLLET ACCORDING TO THE EMBODIMENT.

FIG. 3 is a cross-sectional view taken along line A-A of FIG. 2.

FIG. 4 is a view illustrating a tapered portion of a tip portion of the suction collet according to the embodiment.

FIG. 5 is a perspective view illustrating steps of a method for manufacturing an optical component according to an embodiment.

### DETAILED DESCRIPTION

When heat is applied to a component by laser light, thermal stress may accumulate depending on the type of the component. When the component is irradiated with laser light while a suction collet holds the component by suction, the suction collet is heated by the laser light, which may lead to an excessive temperature rise. Therefore, it is required to join the component while preventing an excessive temperature rise.

An object of the present disclosure is to provide a suction collet and a method for manufacturing an optical component that are capable of joining a component while preventing an excessive temperature rise.

According to the present disclosure, the component can be joined while preventing an excessive temperature rise.

First, embodiments of a suction collet and a method for manufacturing an optical component according to the present disclosure will be listed and described. (1) A suction collet according to the present embodiment includes a main body portion including a hollow portion for taking in air; and a tip portion for holding a component by suction through the intake of air in the hollow portion. The tip portion includes, on an outer periphery of the tip portion, a reflection portion that is a gold-plated portion.

In the suction collet, air is drawn in from the hollow portion of the main body portion, thereby causing the tip portion to hold the component by suction. The reflection portion is provided on the outer periphery of the tip portion that holds the component by suction. Therefore, when the component held by suction is irradiated with laser light to join the component, the laser light with which the suction collet is irradiated is reflected by the reflection portion. Therefore, the component can be joined while preventing an excessive temperature rise of the suction collet. The reflection portion is a gold-plated portion. Since gold has a higher reflectivity of light compared to other materials, the laser light can be more reliably reflected. Therefore, a temperature rise of the suction collet can be more reliably prevented.

(2) In (1) above, the tip portion may include a tapered portion that tapers toward a tip of the suction collet, and the reflection portion may be provided on the tapered portion. In this case, since the tip portion includes the tapered portion that tapers, the component to be held by suction can be easily observed. Therefore, the component can be easily joined.

(3) In (1) or (2) above, the tip portion may include, between a tip of the suction collet and the reflection portion, a heating portion that is not gold-plated. In this case, the heating portion comes into contact with the component held by suction, so that the temperature of the component can be prevented from decreasing.

(4) A method for manufacturing an optical component according to the present disclosure uses a suction collet which includes a main body portion and a tip portion and in which a reflection portion that is a gold-plated portion is provided on an outer periphery of the tip portion. The method for manufacturing an optical component includes a step of applying solder to a predetermined position; a step of bringing the tip portion of the suction collet into contact with a component to hold the component by suction; a step of bringing the component into contact with the solder while the component is held by suction; and a step of irradiating the component with laser light to melt the solder.

In the method for manufacturing an optical component, the solder is applied to the predetermined position, and the component held on the tip portion of the suction collet by suction comes into contact with the solder. The component is irradiated with the laser light, and the solder is melted by the laser light, thereby joining the component held by suction. When the component is irradiated with the laser light, the reflection portion of the tip portion of the suction collet reflects the laser light, so that the component can be joined while preventing an excessive temperature rise of the suction collet. Since the reflection portion is a gold-plated portion, similarly to the suction collet described above, the laser light can be more reliably reflected, and a temperature rise of the suction collet can be more reliably prevented.

Specific examples of a suction collet and a method for manufacturing an optical component according to embodiments of the present disclosure will be described below with reference to the drawings. In the description of the drawings, the same or corresponding elements are denoted by the same reference signs, and redundant descriptions are omitted as appropriate. The drawings may be depicted in a partially simplified or exaggerated manner for ease of understanding, and dimensional ratios and the like are not limited to those illustrated in the drawings.

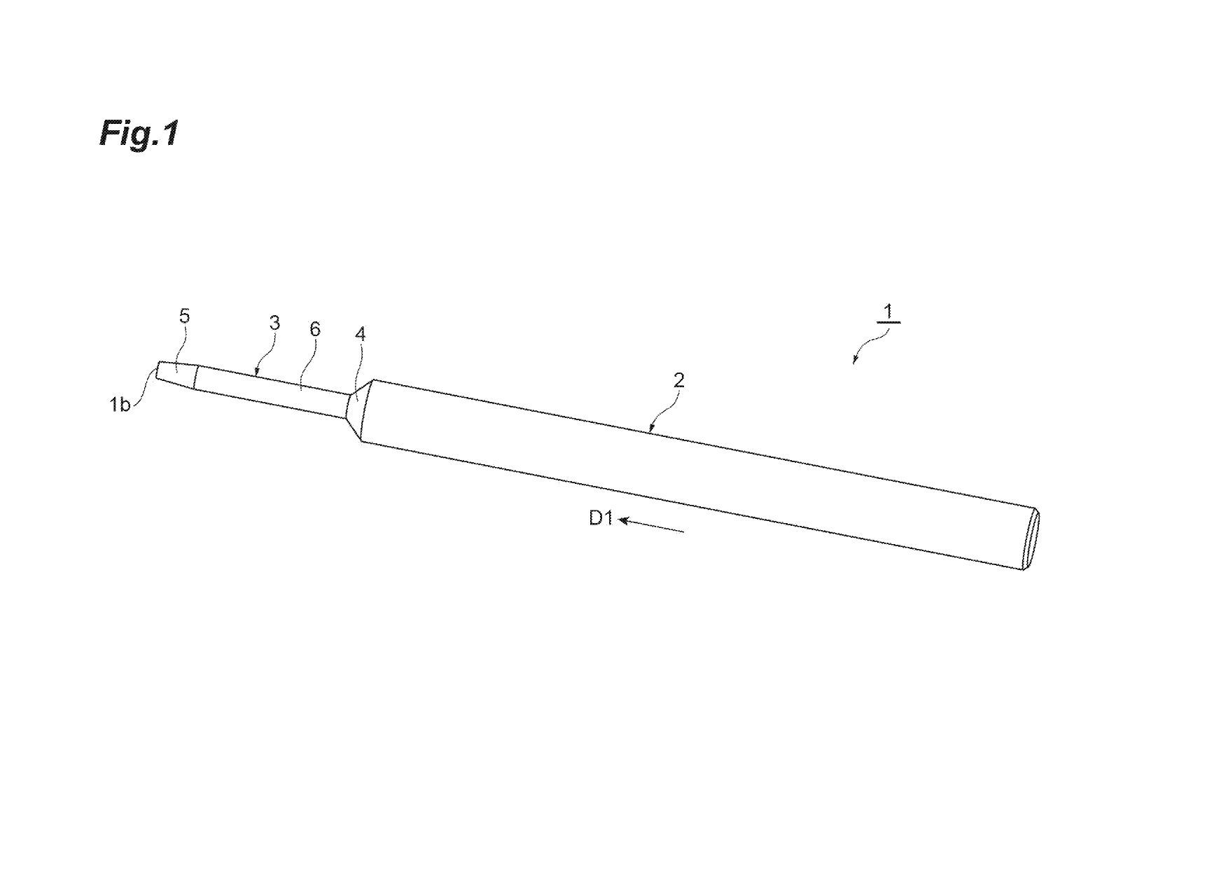

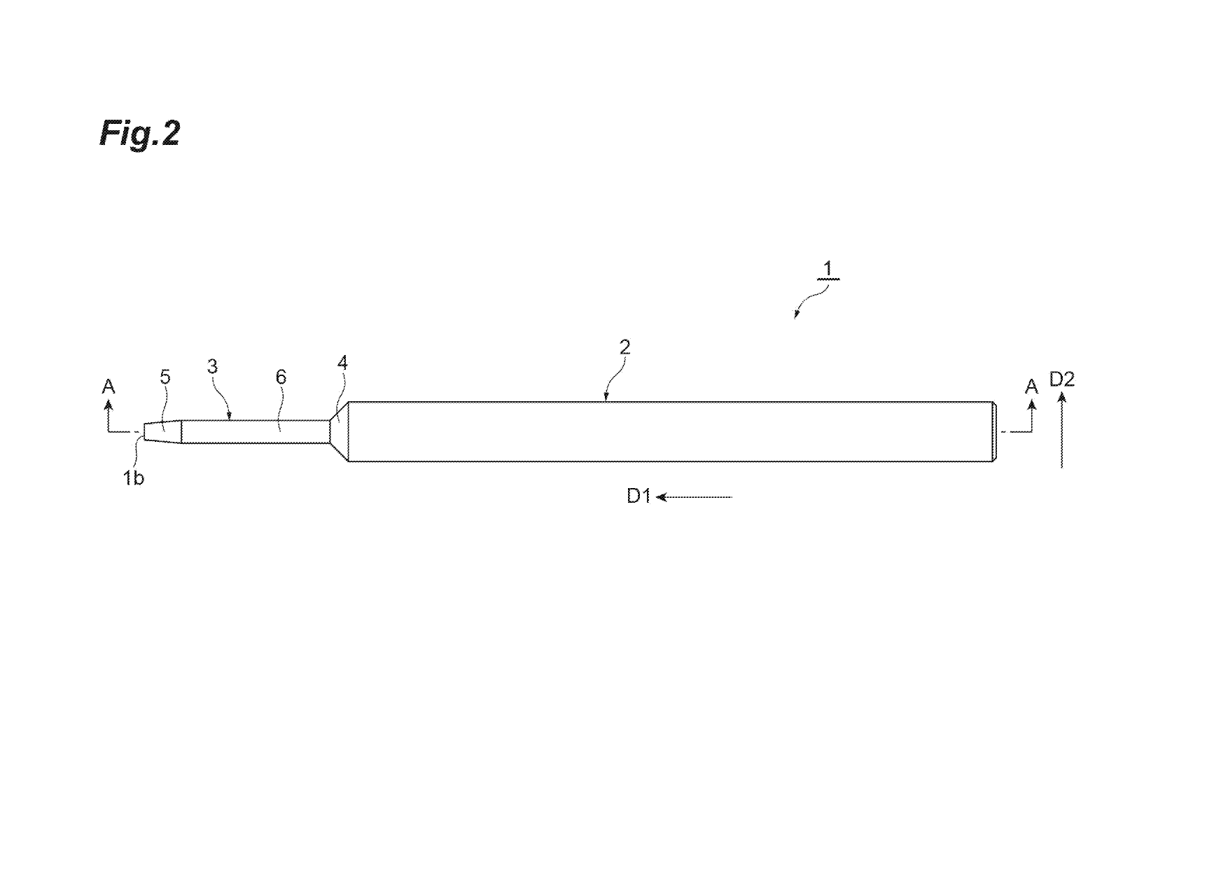

FIG. 1 is a perspective view illustrating a suction collet 1 according to an embodiment. FIG. 2 is a side view illustrating the suction collet 1. As illustrated in FIGS. 1 and 2, the suction collet 1 has a rod shape extending along an extending direction D1 of the suction collet 1. The length of the suction collet 1 in the extending direction D1 is, for example, 20 mm or more and 25 mm or less.

The suction collet 1 includes a main body portion 2 and a tip portion 3 extending in the extending direction D1 from an end portion of the main body portion 2 in the extending direction D1. For example, each of the main body portion 2 and the tip portion 3 has a cylindrical shape. For example, the tip portion 3 is formed integrally with the main body portion 2. However, the tip portion 3 may be a portion separate from the main body portion 2, and for example, a part of the tip portion 3 may be press-fitted into the main body portion 2.

For example, the length of the tip portion 3 in the extending direction D1 is smaller than the length of the main body portion 2 in the extending direction D1. For example, the length of the tip portion 3 in the extending direction D1 is 1/10 or more and 1/3 or less of the length of the main body portion 2 in the extending direction D1. For example, the length of the tip portion 3 in the extending direction D1 is 3 mm or more and 7 mm or less, and the length of the main body portion 2 in the extending direction D1 is 15 mm or more and 30 mm or less. For example, the outer diameter of the tip portion 3 is smaller than the outer diameter of the main body portion 2. In this case, a component held on the tip portion 3 by suction can be easily observed.

For example, the outer diameter of the tip portion 3 is 1/5 or more and 1/2 or less of the outer diameter of the main body portion 2. For example, the outer diameter of the tip portion 3 is 0.3 mm or more and 1 mm or less, and the outer diameter of the main body portion 2 is 1 mm or more and 2 mm or less. The suction collet 1 includes, for example, an inclined portion 4 located between the main body portion 2 and the tip portion 3. The outer peripheral surface of the inclined portion 4 is inclined with respect to the extending direction D1. The inclined portion 4 has, for example, a frustoconical shape. The outer diameter of the inclined portion 4 decreases from the main body portion 2 toward the tip portion 3.

The tip portion 3 includes, for example, a tapered portion 5 extending from a tip 1b of the suction collet 1, and a tubular portion 6 extending from the tapered portion 5 in a direction opposite to the extending direction D1. For example, the length of the tapered portion 5 in the extending direction D1 is smaller than the length of the tubular portion 6 in the extending direction D1. For example, the length of the tapered portion 5 in the extending direction D1 is 1/10 or more and 1/3 or less of the length of the tubular portion 6 in the extending direction D1. For example, the length of the tapered portion 5 in the extending direction D1 is 0.5 mm or more and 2 mm or less, and the length of the tubular portion 6 in the extending direction D1 is 3 mm or more and 10 mm or less. The outer diameter of the tapered portion 5 decreases toward the tip 1b. The outer diameter of the tubular portion 6 is constant. The tubular portion 6 extends from an end portion of the tapered portion 5, the end portion being in a direction opposite to the extending direction D1, in the opposite direction. The tubular portion 6 extends from the tapered portion 5 to the inclined portion 4.

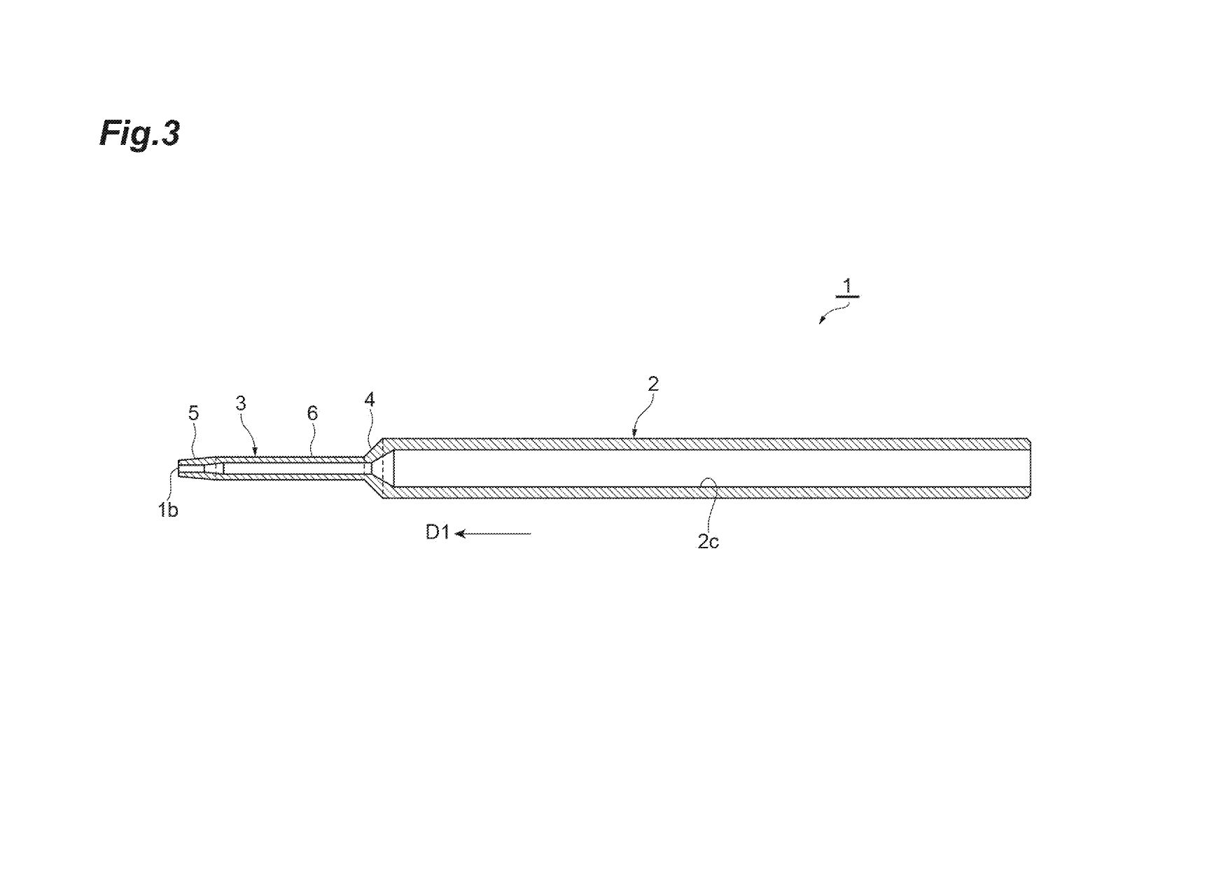

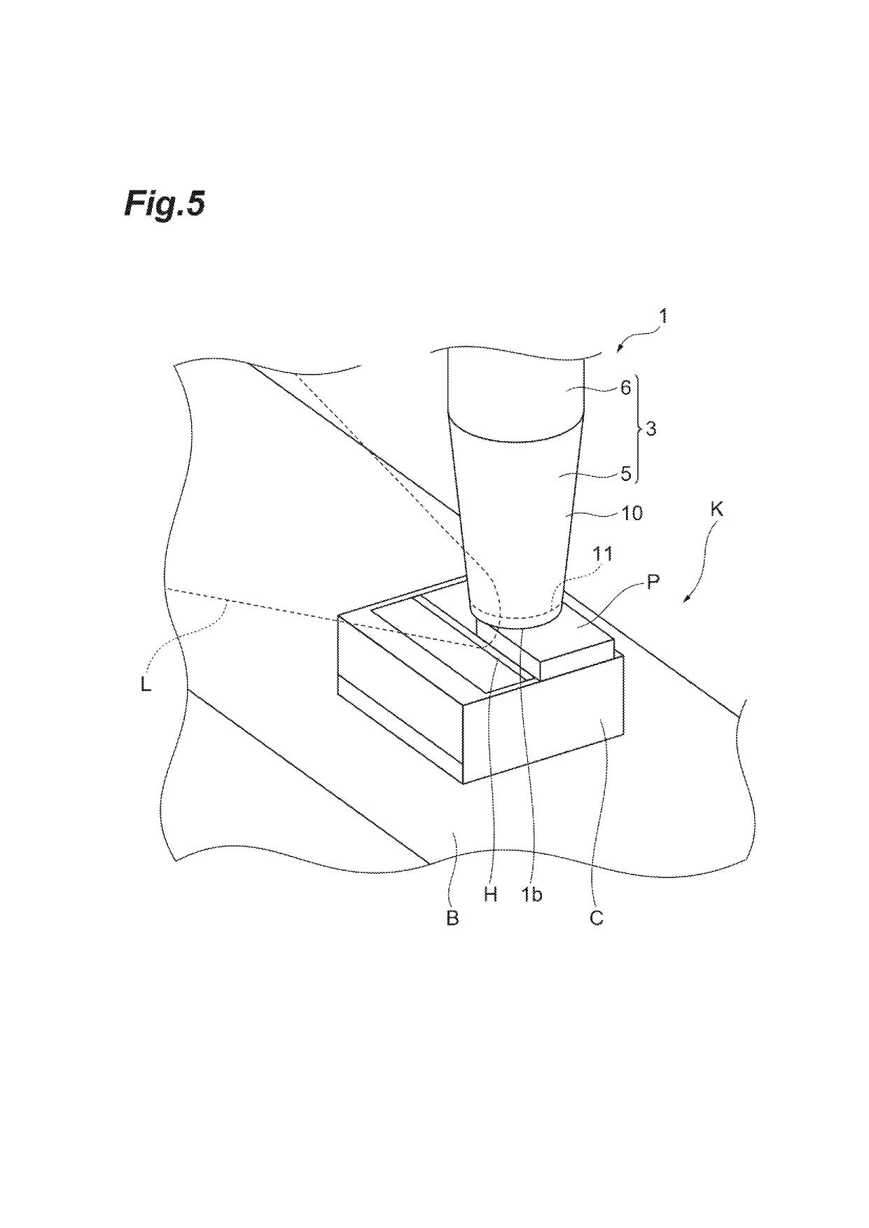

FIG. 3 is a cross-sectional view taken along line A-A of FIG. 2. As illustrated in FIG. 3, the main body portion 2 includes a hollow portion 2c for drawing in air. The tip portion 3 holds a component P (see FIG. 5) by suction through the intake of air in the hollow portion 2c. In the suction collet 1, air is drawn in from the hollow portion 2c, thereby causing the tip portion 3 to hold the component P at the tip 1b by suction.

The tip 1b has a plane surface perpendicular to the extending direction D1. The plane surface touches the component P for holding. The plane surface is a plane surface parallel to a direction D2. The hollow portion 2c communicates with the internal space of the inclined portion 4 and the internal space of the tip portion 3. For example, the inner diameter of the hollow portion 2c (the inner diameter of the main body portion 2) is larger than the maximum value of the inner diameter of the tip portion 3. For example, the diameter of the hollow portion 2c is 3 times or more and 5 times or less the maximum value of the inner diameter of the tip portion 3. For example, the diameter of the hollow portion 2c is 0.7 mm or more and 1.5 mm or less, and the maximum value of the inner diameter of the tip portion 3 is 0.1 mm or more and 0.5 mm or less.

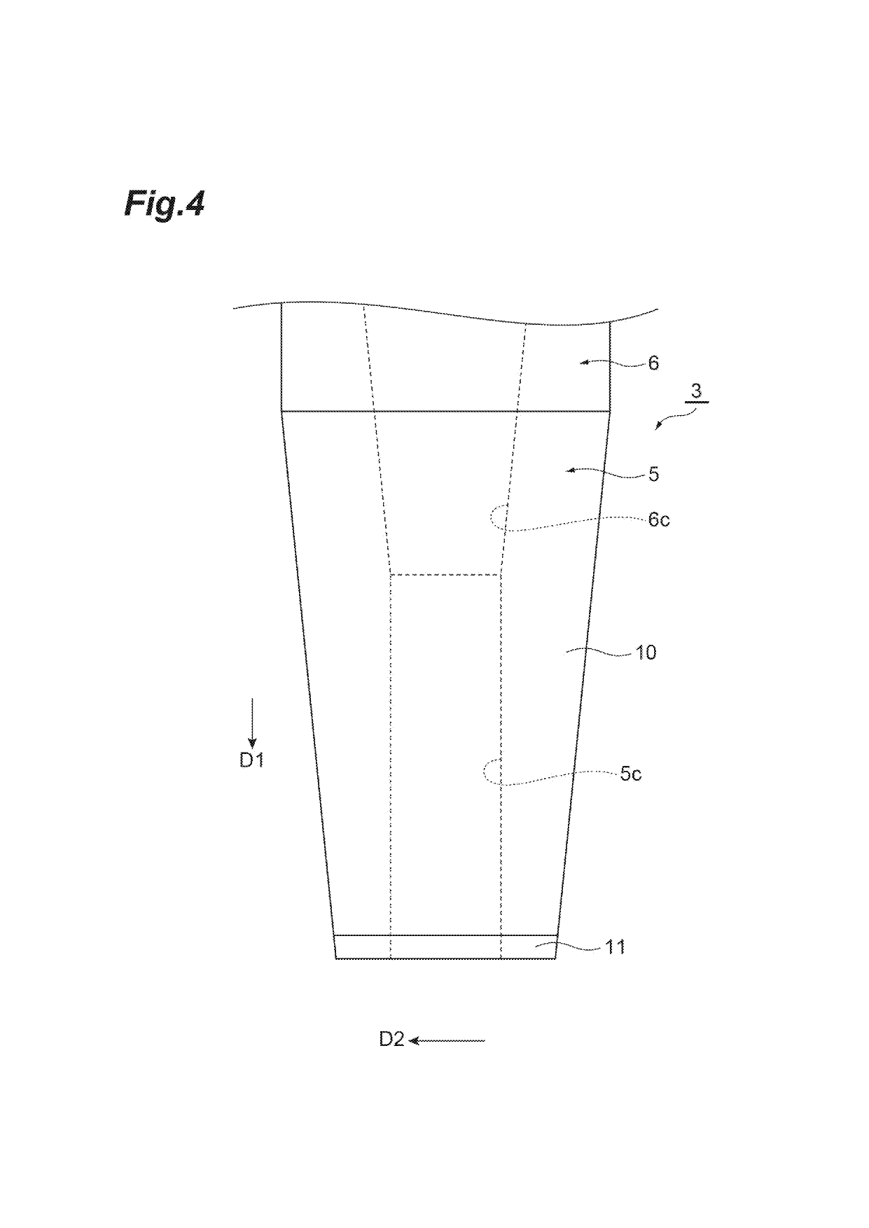

FIG. 4 is an enlarged side view of the tapered portion 5 and the tubular portion 6 of the tip portion 3. As illustrated in FIG. 4, the internal space of the tip portion 3 includes an inner surface 5c located inside the tapered portion 5, and a tapered surface 6c located inside the tapered portion 5 and the tubular portion 6. The inner surface 5c is located between the tapered surface 6c and the tip 1b. The inner diameter of the inner surface 5c is constant. The inner diameter of the tapered surface 6c decreases as the tapered surface 6c approaches the inner surface 5c.

The tip portion 3 includes a reflection portion 10 on the outer periphery of the tip portion 3. The reflection portion 10 is a gold-plated portion. The reflection portion 10 is provided, for example, on the tapered portion 5. The reflection portion 10 may be provided on the tubular portion 6. The reflection portion 10 is a portion that reflects laser light. Since gold plating having an emissivity of 0.02 is applied to the reflection portion 10, the laser light is reflected with almost no absorption. Therefore, the reflection portion 10 does not generate heat even when irradiated with laser light since the reflection portion 10 reflects the laser light.

For example, the tip portion 3 includes a heating portion 11 between the tip 1b of the suction collet 1 and the reflection portion 10. The heating portion 11 is a portion that is not gold-plated. The heating portion 11 is, for example, a portion from which the gold plating of the reflection portion 10 is removed by filing. In the present embodiment, the heating portion 11 is a portion in which a cemented carbide is exposed. In the heating portion 11, since a cemented carbide having an emissivity of approximately 0.3 to 0.4 is exposed, a part of the laser light is absorbed and converted into heat. The heating portion 11 is a portion that comes into contact with the component P that the suction collet 1 holds by suction.

Next, a method for manufacturing an optical component according to the present embodiment will be described. The method for manufacturing an optical component uses the suction collet 1 which includes the main body portion 2 and the tip portion 3 and in which the reflection portion 10 that is a gold-plated portion is provided on the outer periphery of the tip portion 3. Hereinafter, an example of a method for manufacturing an optical component K including the component P will be described with reference to FIG. 5. The optical component K includes a substrate B, a carrier C mounted on the substrate B, and the component P. The component P is a minute component, and for example, the component P has a size of 0.5 mm x 1.0 mm. The component P has, for example, a rectangular parallelepiped shape. The component P is, as one example, an LD chip.

Solder H is applied to a predetermined position (a step of applying solder). For example, the material of the solder H is gold-tin (Ausn), and the melting point of the solder H is 283°C. The solder H may be vapor-deposited under the component P. Then, the suction collet 1 holds the component P by suction. At this time, the tip portion 3 of the suction collet 1 is brought into contact with the component P to hold the component P by suction (a step of holding the component by suction). More specifically, by drawing in air from the hollow portion 2c of the main body portion 2 while the tip 1b of the suction collet 1 is in contact with the component P, the component P is held on the tip portion 3 by suction.

The suction collet 1 is moved while the component P is held on the tip portion 3 by suction, to bring the component P into contact with the solder H (a step of bringing the component into contact with the solder). Then, the component P is irradiated with laser light L to melt the solder H (a step of melting the solder). For example, the wavelength of the laser light L is 940 nm, and the irradiation time of the laser light L is 3 seconds or more and 5 seconds or less. The spot diameter of the laser light L is, as one example, 0.1 mm or more and 0.3 mm or less. Not only the component P but also the suction collet 1 may be irradiated with the laser light L. The laser light L heats the heating portion 11, and is reflected by the reflection portion 10. The solder H melted under the component P is cured between the component P and the carrier C, so that the mounting of the component P is completed and the series of steps are completed.

Next, the effects and advantages obtained from the suction collet 1 and the method for manufacturing an optical component according to the present embodiment will be described. In the suction collet 1, air is drawn in from the hollow portion 2c of the main body portion 2, thereby causing the tip portion 3 to hold the component P by suction. The reflection portion 10 is provided on the outer periphery of the tip portion 3 that holds the component P by suction. Therefore, when the component P held by suction is irradiated with the laser light L to join the component P, the laser light L with which the suction collet 1 is irradiated is reflected by the reflection portion 10. Therefore, the component P can be joined while preventing an excessive temperature rise of the suction collet 1. The reflection portion 10 is a gold-plated portion. Since gold has a higher reflectivity of light compared to other materials, the laser light L can be more reliably reflected. Therefore, a temperature rise of the suction collet 1 can be more reliably prevented.

As described above, the tip portion 3 may include the tapered portion 5 that tapers toward the tip 1b of the suction collet 1, and the reflection portion 10 may be provided on the tapered portion 5. In this case, since the tip portion 3 includes the tapered portion 5 that tapers, the component P to be held by suction can be easily observed. Therefore, the component P can be easily joined.

As described above, the tip portion 3 may include, between the tip 1b of the suction collet 1 and the reflection portion 10, the heating portion 11 that is not gold-plated. In this case, the heating portion 11 comes into contact with the component P held by suction, so that the temperature of the component P can be prevented from decreasing.

In the method for manufacturing an optical component according to the present embodiment, the solder H is applied to the predetermined position, and the component P held on the tip portion 3 of the suction collet 1 by suction comes into contact with the solder H. The component P is irradiated with the laser light L, and the solder H is melted by the laser light L, thereby joining the component P held by suction. When the component P is irradiated with the laser light L, the reflection portion 10 of the tip portion 3 of the suction collet 1 reflects the laser light L, so that the component P can be joined while preventing an excessive temperature rise of the suction collet 1. Since the reflection portion 10 is a gold-plated portion, similarly to the suction collet 1 described above, the laser light L can be more reliably reflected, and a temperature rise of the suction collet 1 can be more reliably prevented.

The embodiments of the suction collet and the method for manufacturing an optical component according to the present disclosure have been described above. However, the suction collet and the method for manufacturing an optical component according to the present disclosure are not limited to the contents of the embodiment described above, and may be modified within the scope of the concept described in the claims. That is, the shapes, sizes, materials, numbers, and disposition modes of the respective portions of the suction collet according to the present disclosure, as well as the contents and order of the steps of the method for manufacturing an optical component, can be changed as appropriate within the scope of the concept.

For example, in the embodiment described above, an example in which the heating portion 11 is provided at the tip 1b of the suction collet 1 has been described. However, the heating portion 11 may not be provided at the tip 1b of the suction collet 1. In the embodiment described above, an example in which the component P is an LD chip has been described. However, the component P may be other than an LD chip. In this manner, the suction collet and the method for manufacturing an optical component according to the present disclosure can be applied to various components.

What is claimed is:

1. A suction collet comprising:
a main body portion including a hollow portion for taking in air; and
a tip portion for holding a component by suction through the intake of air in the hollow portion,
wherein the tip portion includes, on an outer periphery of the tip portion, a reflection portion that is a gold-plated portion.

2. The suction collet according to claim 1,
wherein the tip portion includes a tapered portion that tapers toward a tip of the suction collet, and
the reflection portion is provided on the tapered portion.

3. The suction collet according to claim 1,
wherein the tip portion includes, between a tip of the suction collet and the reflection portion, a heating portion that is not gold-plated.

4. A method for manufacturing an optical component that uses a suction collet which includes a main body portion and a tip portion and in which a reflection portion that is a gold-plated portion is provided on an outer periphery of the tip portion, the method comprising:
a step of applying solder to a predetermined position;
a step of bringing the tip portion of the suction collet into contact with a component to hold the component by suction;
a step of bringing the component into contact with the solder while the component is held by suction; and
a step of irradiating the component with laser light to melt the solder.
